(19) United States
(12) Patent Application Publication
(10) Pub. No.: US 2015/0179692 A1
(43) Pub. Date: Jun. 25, 2015

(54) SOLID-STATE IMAGING APPARATUS AND METHOD OF MANUFACTURING THE SAME

(71) Applicant: CANON KABUSHIKI KAISHA, Tokyo (JP)

(72) Inventors: Mariko Furuta, Yokohama-shi (JP); Aiko Kato, Machida-shi (JP); Takehiro Toyoda, Machida-shi (JP)

(21) Appl. No.: 14/562,943

(22) Filed: Dec. 8, 2014

(30) Foreign Application Priority Data
Dec. 20, 2013 (JP) 2013-264505

(51) Int. Cl. H01L 27/146

(52) U.S. Cl. CPC H01L 27/14636; H01L 27/14621; H01L 27/14623; H01L 27/14685

(57) ABSTRACT

A method of manufacturing a solid-state imaging apparatus is provided. The method includes forming, above a substrate having an effective pixel region and a non-effective pixel regions, a structure including first and second members located above the effective and non-effective pixel regions respectively, and a third member covering the first and second members, forming, above the third member, a mask having first and second apertures located above the first and second members respectively, and forming a first hole exposing the first member by etching the structure through the first aperture and a second hole exposing the second member by etching the structure through the second aperture. In the etching, the first and second holes are concurrently formed and etching of the structure is finished based on that the second hole has reached the second member.

### BACKGROUND OF THE INVENTION

1. Field of the Invention

The present invention relates to a solid-state imaging apparatus and a method of manufacturing the same.

2. Description of the Related Art

There have been various proposals for improving the light use efficiency of a solid-state imaging apparatus. Japanese Patent Laid-Open No. 2012-227478 has proposed a solid-state imaging apparatus including a light waveguide on a photoelectric conversion portion and a color filter on the light waveguide. Both the light waveguide and the color filter are embedded in a hole formed in an insulating layer. The color filter has a tapered portion, and also functions as a light waveguide. The solid-state imaging apparatus in Japanese Patent Laid-Open No. 2012-227478 has such a two-stage embedded member.

### SUMMARY OF THE INVENTION

The following method can be used to form a two-stage structure like that disclosed in Japanese Patent Laid-Open No. 2012-227478. That is, first of all, a first-stage light waveguide is formed in an insulating layer on a substrate, and an insulating layer is further formed on the light waveguide. Subsequently, a portion, of this insulating layer, which is located on the light waveguide is removed by etching to form a hole. A second-stage color filter is formed in this hole. In this forming method, the upper surface of the first-stage light waveguide is exposed to etching, which may make the first-stage light waveguide have an unintended shape. Some aspects of the present invention provide a technique capable of accurately forming a hole on a member.

According to some embodiments, a method of manufacturing a solid-state imaging apparatus is provided. The method includes forming, above a substrate having an effective pixel region and a non-effective pixel region, a structure including a first member located above the effective pixel region, a second member located above the non-effective pixel region, and a third member covering the first member and the second member; forming, above the third member, a mask having a first aperture located above the first member and a second aperture located above the second member; and forming a first hole exposing the first member in the structure by etching the structure through the first aperture, and a second hole exposing the second member in the structure by etching the structure through the second aperture, wherein in the etching, the first hole and the second hole are concurrently formed, and etching of the structure is finished based on that the second hole has reached the second member.

According to other some embodiments, a solid-state imaging apparatus comprising a substrate having an effective pixel region including a photoelectric conversion portion and a non-effective pixel region is provided. Above the effective pixel region, a first filling member surrounded by a first insulating film in a first plane along a light-receiving surface of the photoelectric conversion portion and a second filling member surrounded by a second insulating film above the first insulating film in a second plane along the light-receiving surface of the photoelectric conversion portion are provided, a third filling member surrounded by the second insulating film in the second plane is provided above the non-effective pixel region, and the first insulating film is located between the third filling member and the substrate in the first plane.

Further features of the present invention will become apparent from the following description of exemplary embodiments (with reference to the attached drawings).

### BRIEF DESCRIPTION OF THE DRAWINGS

FIG. 1 is a view for explaining the arrangement of a solid-state imaging apparatus according to some embodiments;

FIGS. 2A to 2D are views for explaining a method of manufacturing a solid-state imaging apparatus according to some embodiments;

FIGS. 3A to 3C are views for explaining a method of manufacturing a solid-state imaging apparatus according to some embodiments;

FIGS. 4A to 4D are views for explaining a method of manufacturing a solid-state imaging apparatus according to some embodiments;

FIGS. 5A to 5D are views for explaining a method of manufacturing a solid-state imaging apparatus according to some embodiments;

FIGS. 6A and 6B are views for explaining a method of manufacturing a solid-state imaging apparatus according to some embodiments; and

FIGS. 7A and 7B are views for explaining the arrangement of a solid-state imaging apparatus according to some embodiment.

### DESCRIPTION OF THE EMBODIMENTS

The embodiments of the present invention will be explained below with reference to the accompanying drawings. The same reference numerals throughout various embodiments denote the same elements, and a repetitive description will be omitted. In addition, it is possible to change and combine the embodiments, as needed.

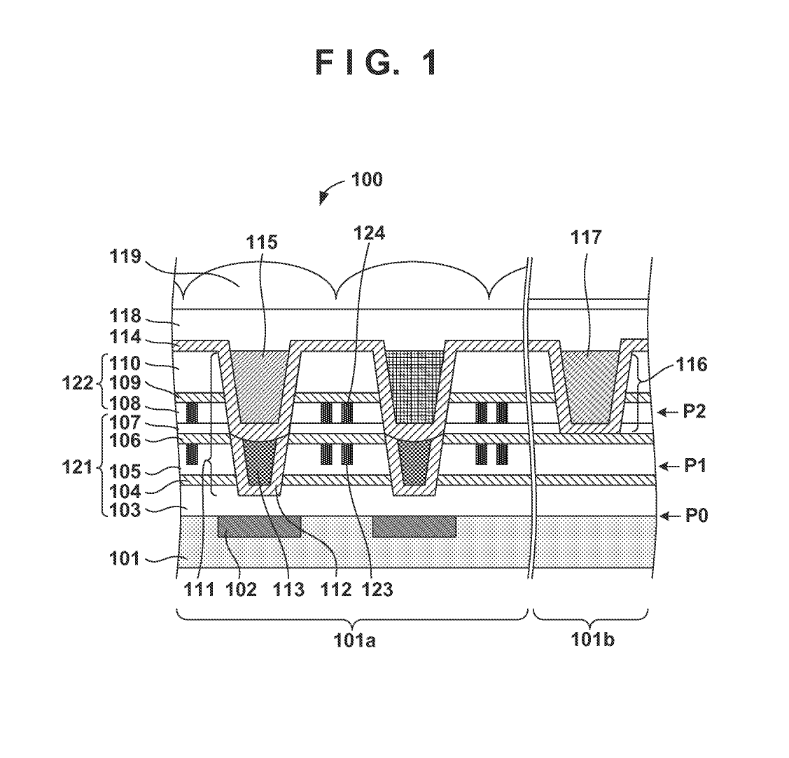

An example of the arrangement of a solid-state imaging apparatus 100 according to some embodiments will be described with reference to FIG. 1. FIG. 1 is a schematic sectional view paying attention to part of the solid-state imaging apparatus 100. The solid-state imaging apparatus 100 according to this embodiment has the components shown in FIG. 1. A semiconductor substrate 101 includes an effective pixel region 101a and a non-effective pixel region 101b. The effective pixel region 101a is a region in which a plurality of pixels which generate a signal corresponding to incident light to the solid-state imaging apparatus 100 are arranged in a two-dimensional array. The non-effective pixel region 101b is a region other than the effective pixel region 101a of the semiconductor substrate 101. The non-effective pixel region 101b can include a peripheral circuit region in which, for example, driving circuits for driving pixels and readout circuits for reading out signals from the pixels are arranged. The non-effective pixel region 101b can include an ineffective pixel region in which optical black pixels and dummy pixels are arranged. Each pixel of the solid-state imaging apparatus 100 includes a photoelectric conversion portion 102 formed on the semiconductor substrate 101 and a transfer transistor (not shown) formed adjacent to the photoelectric conversion portion 102. The semiconductor substrate 101 may have an existing arrangement, and hence a further description of the arrangement will be omitted.

The solid-state imaging apparatus 100 includes, in both the effective pixel region 101a and the non-effective pixel region 101b, a plurality of insulating layers 103 to 110 on the semiconductor substrate 101 in increasing order of distance from the semiconductor substrate 101. In this case, the plurality of insulating layers will be separately described as an insulating film 121 which is a multilayer film including the insulating layers 103 to 107 and an insulating film 122 which is a multilayer film including the insulating layers 108 to 110. The insulating layers 103, 105, 107, 108, and 110 are made of, for example, silicon oxide (SiO), and the insulating layers 104, 106, and 109 are made of, for example, silicon carbide (SiC). An electrically conductive pattern 123 forming a wiring layer is formed in the insulating layer 105. The electrically conductive pattern 123 is made of, for example, copper. The solid-state imaging apparatus 100 may include a barrier metal layer (not shown) between the electrically conductive pattern 123 and the insulating layer 105. The insulating layer 106 covers the upper surface of the electrically conductive pattern 123 to prevent the diffusion of copper atoms. The solid-state imaging apparatus also has a similar electrically conductive pattern in the insulating layer 108.

The solid-state imaging apparatus 100 includes filling portions 111 each surrounded by the multilayer structure of the insulating layers formed on the semiconductor substrate 101 and provided on the corresponding photoelectric conversion portions 102. Each filling portion 111 extends through the insulating layers 104 to 110 and has a bottom surface midway in the insulating layer 103. An insulating layer 112 covers a lower portion of the side surface of each filling portion 111 and the bottom surface of each filling portion 111. The insulating layer 112 is made of, for example, silicon nitride (SiN). The lower portion of each filling portion 111 is provided with a first filling member 113. Each first filling member 113 is surrounded by the insulating film 121 in a first plane P1 along a light-receiving surface P0 of the corresponding photoelectric conversion portion 102. For example, each first filling member 113 is surrounded by the insulating layer 105 of the insulating film 121. Each insulating layer 112 covers the side and bottom surfaces of the corresponding first filling member 113. The first filling members 113 are made of, for example, silicon nitride. An insulating layer 114 covers the upper portion of the side surface of each filling portion 111, the upper surface of each insulating layer 112, and the upper surface of each first filling member 113. The insulating layer 114 is made of, for example, silicon nitride. The upper portion of each filling portion 111 is provided with a second filling member 115. The second filling members 115 are surrounded by the insulating film 122 in a second plane P2 along the light-receiving surface P0 of the photoelectric conversion portion 102. For example, each second filling member 115 is surrounded by the insulating layer 108 of the insulating film 122. The insulating layer 114 covers the side and bottom surfaces of the second filling member 115. Each second filling member 115 in this case is a color filter. The solid-state imaging apparatus 100 may have the second filling members 115 as color filters for a plurality of colors. For example, the second filling members 115 of a plurality of pixels may constitute a color filter array with a Bayer pattern. In the solid-state imaging apparatus 100, the first filling member 113 and the second filling member 115 are stacked on the corresponding photoelectric conversion portion 102.

The multilayer structure of the insulating layers formed on the semiconductor substrate 101 has a filling portion 116 on the non-effective pixel region 101b of the semiconductor substrate 101. The filling portion 116 extends through the insulating layers 107 to 110. The upper surface of the insulating layer 106 forms the bottom surface of the filling portion 116. The insulating layer 114 covers the side and bottom surfaces of the filling portion 116. The filling portion 116 is filled with a third filling member 117. The third filling member 117 is surrounded by the insulating film 122 in the second plane P2 along the light-receiving surface P0 of the photoelectric conversion portion 102. For example, the third filling member 117 is surrounded by the insulating layer 108 of the insulating film 122 in this plane. The insulating layer 114 covers the side and bottom surfaces of the third filling member 117. The insulating layer 114 also covers portions, of the operation unit 110, in which the filling portions 111 and 116 are not formed. Unlike in the effective pixel region 101a, the insulating film 121 is located between the third filling member 117 and the semiconductor substrate 101 in the first plane P1. For example, the insulating layer 105 is located below the third filling member 117. The filling portion 116 may be formed on a portion, of the non-effective pixel region 101b of the semiconductor substrate 101, on which no light-shielding pixel (optical black pixel) is formed, for example, on a peripheral circuit region. In this case, light transmitted through the third filling member 117 does not reach any photoelectric conversion portion 102, and hence the third filling member 117 can be used for any color. In addition, when the filling portion 116 is formed on the photoelectric conversion portion of a light-shielding pixel, a light-shield member for shielding the photoelectric conversion portion against light may be arranged as the third filling member 117 in the filling portion 116.

The solid-state imaging apparatus 100 includes a planarization layer 118 on the insulating layer 114 and the second filling members 115, and a lens layer 119 on the planarization layer 118. A portion, of the lens layer 119, which is located above each photoelectric conversion portion 102 has a shape functioning as an on-chip lens.

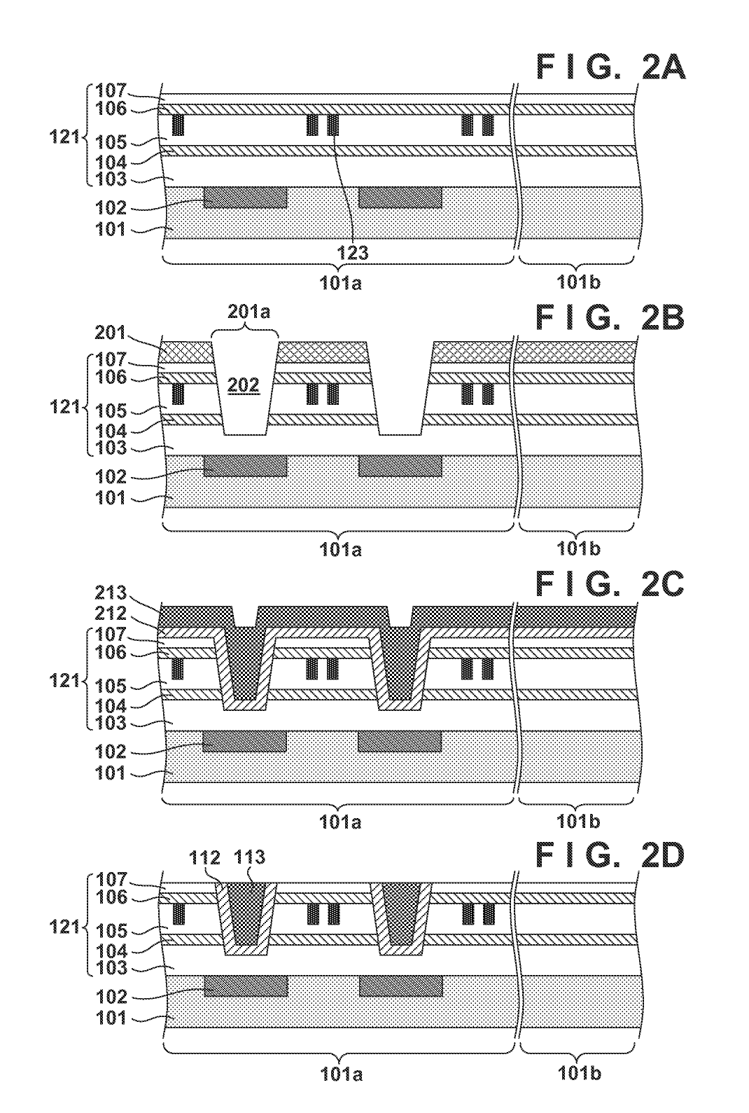

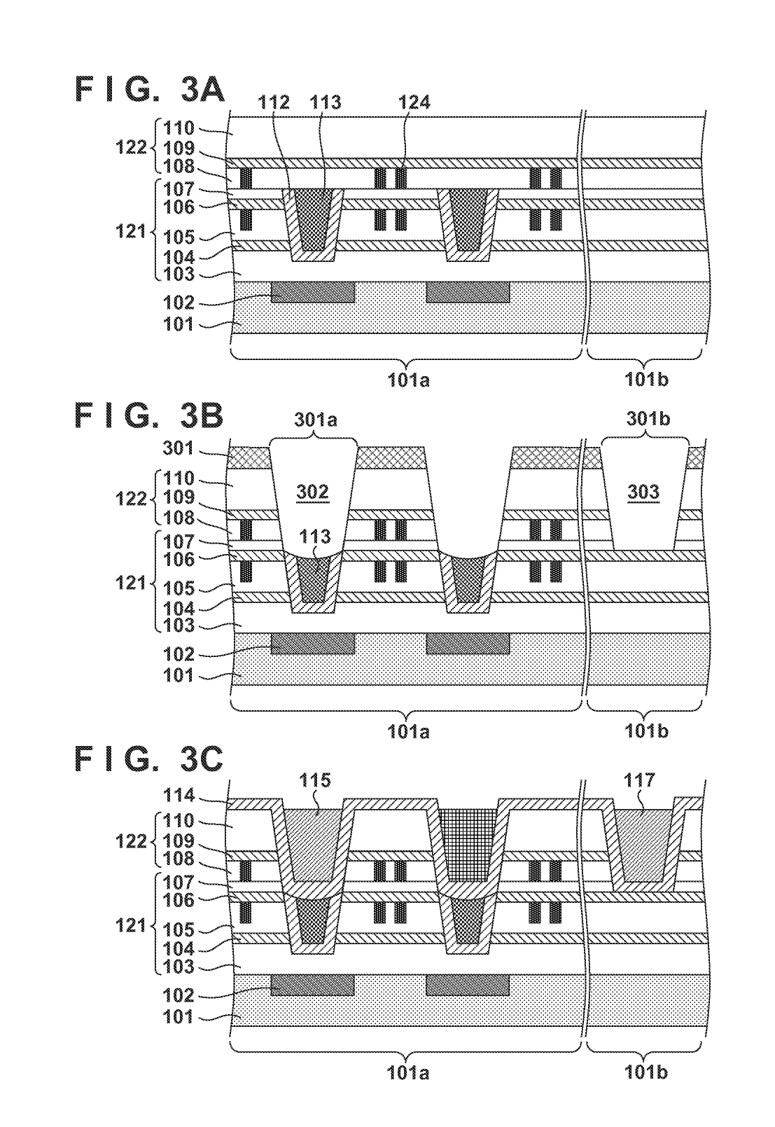

An example of a method of manufacturing the solid-state imaging apparatus 100 will be subsequently described with reference to FIGS. 2A to 2D and 3A to 3C. First of all, as shown in FIG. 2A, the semiconductor substrate 101 is prepared, which includes semiconductor elements such as a photodiode forming each photoelectric conversion portion 102 and a readout transistor. Since the semiconductor substrate 101 including semiconductor elements may be formed by an existing method, a detailed description of the method will be omitted. Subsequently, the insulating film 121 is formed by depositing the insulating layers 103 to 107 on the semiconductor substrate 101 in the order named by using, for example, a CVD method. In this case, the insulating film 121 is a multilayer film including the insulating layers 103 to 107. However, the insulating film 121 may be a monolayer film. The insulating film 121 including the insulating layers 103 to 107 is formed on both the effective pixel region 101a and the non-effective pixel region 101b of the semiconductor substrate 101. The insulating layers 103, 105, and 107 are made of, for example, silicon oxide. The insulating layers 104 and 106 are made of, for example, silicon carbide. After the insulating layer 105 is formed, the electrically conductive pattern 123 is formed before the formation of the insulating layer 106. Since the electrically conductive pattern 123 made of copper may be formed by an existing method such as a damascene method, a detailed description of the method will be omitted. Note that a plug (not shown) for connecting the electrically conductive pattern 123 to an electrode formed on the semiconductor substrate 101 is formed on the insulating layer 103. With the above process, the structure shown in FIG. 2A is formed.

Subsequently, as shown in FIG. 2B, a resist pattern 201 is formed on the insulating film 121 (on the insulating layer 107) by, for example, a photolithography method. The resist pattern 201 has an aperture 201a above each photoelectric conversion portion. Each hole 202 is formed by etching the structure formed on the semiconductor substrate 101 using the resist pattern 201 as a mask. This etching is performed until each hole 202 reaches a midway portion of the insulating layer 103. As an etching method, for example, dry etching such as RIE (Reactive Ion Etching) is used. Since the insulating layers 103, 105, and 107 and the insulating layers 104 and 106 are made of different materials, the type of gas may be switched during etching. With the above process, the structure shown in FIG. 2B is formed.

Subsequently, as shown in FIG. 2C, after the resist pattern 201 is removed, an insulating layer 212 and an insulating layer 213 are deposited in the order named by using, for example, a CVD method. The insulating layer 212 and the insulating layer 213 are made of, for example, silicon nitride. With the above processing, the structure shown in FIG. 2C is formed.

Subsequently, as shown in FIG. 2D, the insulating layer 213 and the insulating layer 212 are polished by using, for example, CMP until the upper surface of the insulating layer 107 is exposed. This removes portions, of the insulating layer 213 and the insulating layer 212, which are located on the insulating layer 107. Portions, of the insulating layer 213 and the insulating layer 212, which have entered the holes 202 remain without being removed. In this manner, a portion, of the insulating layer 212, which is left in each hole 202 becomes the insulating layer 112, and a portion, of the insulating layer 213, which is left in each hole 202 becomes the first filling member 113. With the above process, the structure shown in FIG. 2D is formed.

Subsequently, as shown in FIG. 3A, the insulating film 122 is formed by depositing the insulating layers 108 to 110 on the structure shown in FIG. 2D in the order named by using, for example, a CVD method. In this case, the insulating film 122 is a multilayer film including the insulating layers 108 to 110. However, the insulating film 122 may be a monolayer film. The insulating layers 108 and 110 are made of, for example, silicon oxide. The insulating layer 109 is made of, for example, silicon carbide. The insulating film 122 including the insulating layers 108 to 110 is formed on both the effective pixel region 101a and the non-effective pixel region 101b of the semiconductor substrate 101. An electrically conductive pattern 124 forming a wiring layer is also formed in the insulating layer 108.

Subsequently, as shown in FIG. 3B, a resist pattern 301 is formed on the insulating film 122 (on the operation unit 110) by, for example, a photolithography method. The resist pattern 301 has apertures 301a on the non-effective pixel region 101b, and an aperture 301b on the non-effective pixel region 101b. Holes 302 and 303 are then formed by etching the structure formed on the semiconductor substrate 101 by using the resist pattern 301 as a mask. Etching for the formation of each hole 302 is performed concurrently with etching for the formation of the hole 303. In addition, this etching is performed to expose at least the insulating film 121 through the hole 303. In this case, etching is performed until the hole reaches the upper surface of the insulating layer 106 which is the uppermost layer of the insulating film 121. As an etching method, for example, RIE (Reactive Ion Etching) is used. Since the insulating layers 103, 105, and 107 and the insulating layers 104 and 106 are made of different materials, the type of gas may be switched during etching.

An etching process for forming the holes 302 and 303 will be described in detail below. First of all, when etching the insulating layers 108 to 110, since a portion below each aperture 301a has the same multilayer structure as that of a portion below an aperture 301b, etching proceeds in the same manner. In order to match the etching rate for the holes 302 with that for the hole 303, the apertures 301a and 301b may have the same shape and dimensions (for example, the same width or diameter). As the insulating layers 108 to 110 are etched, the upper surface of each first filling member 113 is exposed under the corresponding aperture 301a, and the upper surface of the insulating layer 107 is exposed under the aperture 301b. Subsequently, etching is performed to remove a portion, of the insulating layer 107, which is located under the corresponding aperture 301b. Since the insulating layer 107 is made of silicon oxide, this etching uses a fluorocarbon-based etching gas as an etching agent. In this case, the silicon oxide of the etched layer reacts with a fluorocarbon-based etching gas by the etching reaction to generate a gas containing CO as a component during the etching. Since the insulating layer 106 is made of silicon carbide, when the etching of the insulating layer 107 is complete and the hole 303 reaches the insulating layer 106, CO ceases to be generated. For this reason, it is possible to detect that the etching of the insulating layer 107 is complete and the hole 303 has reached the insulating layer 106, by monitoring the emission intensity of light having an emission spectrum (for example, 483 nm) of a CO plasma using a dry etching apparatus. More specifically, when the emission intensity of light having an emission spectrum of a CO plasma has decreased, it can be detected that the hole 303 has reached the insulating layer 106, and the insulating layer 106 is exposed. Alternatively, when an etching gas can react with the insulating layer 106 under the insulating layer 107, it is possible to monitor the emission intensity of the emission spectrum of a plasma generated by the gas generated when the etching gas reacts with the material (for example, silicon carbide) of the insulating layer 107. In this case, when the emission intensity increases, it is possible to detect that the hole 303 has reached the insulating layer 106, and the insulating layer 106 is exposed. The insulating layer 106 or the insulating layer 107 functions in this manner as a member for detecting the end of etching.

As shown in FIG. 3B, when etching the insulating layer 107, both the upper surface of each insulating layer 112 and the upper surface of each first filling member 113 may be etched. In this embodiment, however, since it is possible to stop etching based on when the hole 303 exposes the insulating layer 106, it is possible to control the etching amounts of the upper surface of each insulating layer 112 and the upper surface of each first filling member 113. For example, etching is stopped immediately after it is detected that the holes 303 have reached the insulating layer 106. This makes it possible to suppress the excessive etching of the insulating layers 112 and the first filling members 113 and accurately form the first filling members 113. In order to further improve the accuracy, a material may be selected for each insulating layer such that the selection ratio between the insulating layer 107 and the insulating layer 106 becomes higher than that between the insulating layer 107 and the first filling members 113.

Furthermore, in this embodiment in FIGS. 1 to 3C, in the state (FIG. 3A) before the etching for the formation of the holes 302 and 303, the height of the upper surface of each first filling member 113 from the semiconductor substrate 101 is higher than the height of the upper surface of the insulating layer 106 from the semiconductor substrate 101. For this reason, the insulating layers 108 to 110 on the first filling members 113 can be reliably removed by the etching in FIG. 3B. With the above process, the structure shown in FIG. 3B is formed.

Subsequently, as shown in FIG. 3C, after the removal of the resist pattern 301, the insulating layer 114 is deposited by using, for example, a CVD method. The insulating layer 114 is made of, for example, silicon nitride. The insulating layer 114 functions as a passivation film. Thereafter, the second filling members 115 formed from color filters are embedded in the holes 302, and the third filling member 117 formed from a color filter is embedded in the hole 303. With the above process, the structure shown in FIG. 3C is formed. Thereafter, the planarization layer 118 and the lens layer 119 are formed to form the solid-state imaging apparatus 100 in FIG. 1. Although the third filling member 117 need not be embedded in the hole 303, embedding the third filling member 117 in the hole 303 can reduce the irregularity caused by the formation of the hole 303 and facilitates forming the planarization layer 118 and the lens layer 119. A combination of the first filling members 113 provided in the holes 202 in FIG. 2B and the second filling members 115 provided in the holes 302 in FIG. 3B corresponds to the filling portions 111 in FIG. 1, and the third filling member 117 provided in the hole 303 in FIG. 3B corresponds to the filling portion 116.

In the solid-state imaging apparatus 100, each filling portion 111 has a tapered portion such that the area of the bottom surface is smaller than that of the upper surface. Both the insulating layer 112 and the first filling member 113 formed on the lower side of the corresponding filling portion 111 are made of SiN, and have a higher refractive index than the surrounding insulating layers. For this reason, the insulating layer 112 and the first filling member 113 function as a light waveguide. When the first filling member 113 functions as a light waveguide, the formation accuracy of the first filling member 113 influences the image quality obtained by the solid-state imaging apparatus 100. In this embodiment, since the first filling member 113 can be accurately formed, a deterioration in the image quality obtained by the solid-state imaging apparatus 100 can be suppressed.

In the above embodiment, although SiN is embedded as the first filling member 113 in the lower side of each filling portion 111, an inorganic member, organic member, or metal member may be embedded instead of SiN in other embodiments. When embedding a metal member as the first filling member 113, the metal member may form part of a wiring layer.

In the above embodiment, although the second filling member 115 formed from a color filter is embedded in the upper side of each filling portion 111, a colorless transparent inorganic material or organic material may be embedded instead of a color filter as the second filling member 115 in other embodiments. Alternatively, nothing may be embedded in each hole 302. In addition, as the first filling member 113 or the second filling member 115, each filling portion may be formed as a light-shielding portion instead of a light-transmitting portion by using a light-shielding material such as a metal instead of a light-transmitting material. In this case, each filling portion as a light-shielding portion is provided on a portion between photoelectric conversion portions instead of on a corresponding photoelectric conversion portion. Such a filling portion as a light-shielding portion can suppress the generation of stray light in the solid-state imaging apparatus 100. When using an electrically conductive material such as a metal for the first filling member 113 or the second filling member 115, the electrically conductive material may form part of a wiring. In addition, when a member other than the second filling member 115 is embedded in the upper side of the corresponding filling portion 111, the solid-state imaging apparatus may include the second filling member 115 between this member and the microlens.

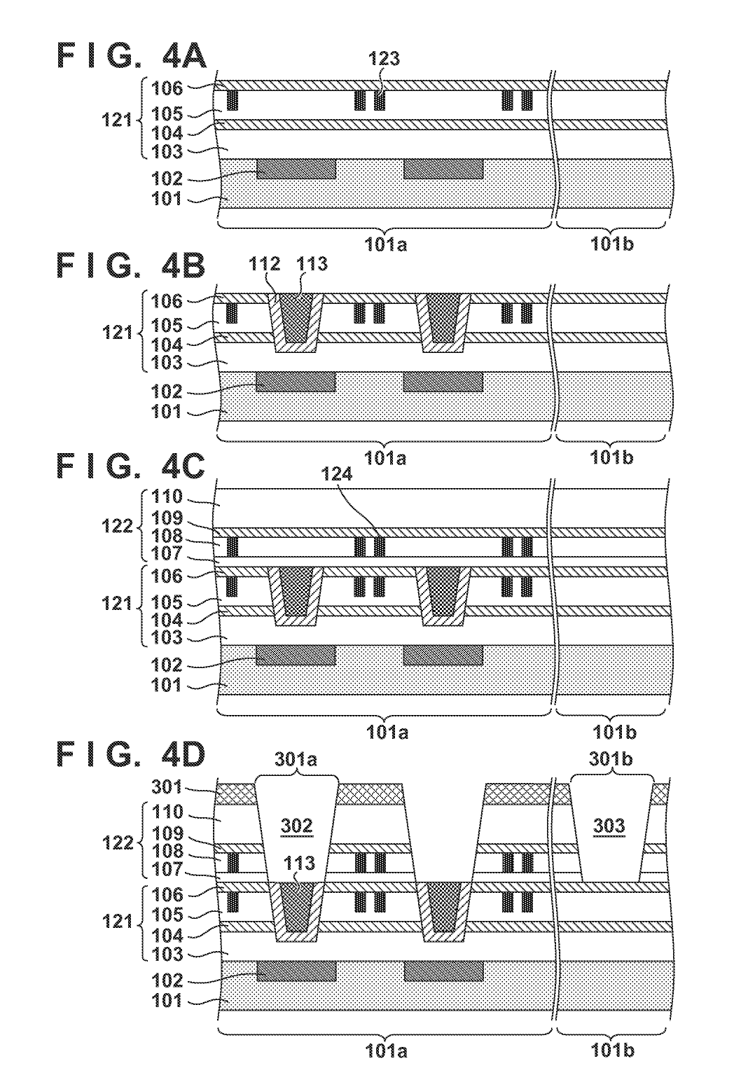

A method of manufacturing a solid-state imaging apparatus according to another embodiment will be described next with reference to FIGS. 4A to 4D. The arrangement of the solid-state imaging apparatus manufactured by this method is the same as the solid-state imaging apparatus 100 in FIG. 1. First of all, in the same manner as in the process described with reference to FIG. 2A, an insulating film 121 including insulating layers 103 to 106 is formed on a semiconductor substrate 101. This forms the structure shown in FIG. 4A.

Subsequently, in the same manner as in the process described with reference to FIGS. 2B to 2D, holes are formed in portions, of the insulating layers 103 to 106, which are located above corresponding photoelectric conversion portions 102, and an insulating layer 112 and a first filling member 113 are formed in each hole. This forms the structure shown in FIG. 4B.

Subsequently, in the same manner as in the process described with reference to FIG. 3A, insulating layers 107 and 110 are formed. This forms the structure shown in FIG. 4C. In the manufacturing method shown in FIGS. 2A to 3C, the insulating layer 107 is formed before the formation of the insulating layers 112 and the first filling members 113. In contrast to this, in the manufacturing method shown in FIGS. 4A to 4D, the insulating layer 107 is formed after the formation of the insulating layers 112 and the first filling members 113. As a result, unlike in the manufacturing method shown in FIGS. 2A to 3C, in which the upper surface of each first filling member 113 is at a position higher than the upper surface of the insulating layer 106 at the stage shown FIG. 3A, in the manufacturing method shown in FIGS. 4A to 4D, the upper surface of each first filling member 113 is at the same height as the upper surface of the insulating layer 106. In this case, the height of the upper surface (the light-receiving surface P0 in FIG. 1) of the semiconductor substrate 101 is regarded as a reference height. The same applies to the following description.

Subsequently, in the same manner as in the process described with reference to FIG. 3B, a resist pattern 301 is formed on the insulating layer 110, and the holes 302 and 303 are formed by etching using the resist pattern 301 as a mask. This forms the structure shown in FIG. 4D. In the manufacturing method shown in FIGS. 4A to 4D, it is also detected that the hole 303 has reached the insulating layer 106. In this embodiment, since the upper surface of each first filling member 113 is at the same height as the upper surface of the insulating layer 106, it is possible to stop etching when it is detected that the hole 303 has reached the insulating layer 106. This makes the bottom surface of the hole 302 flush with the upper surface of the first filling member 113. In addition, in consideration of variations in etching, etching may be continued for a predetermined time after it is detected that the hole 303 has reached the insulating layer 106. This can reliably remove a portion, of the insulating layer 107, which is on the first filling member 113. Thereafter, a solid-state imaging apparatus is complete in the same manner as in the process described with reference to FIG. 3C.

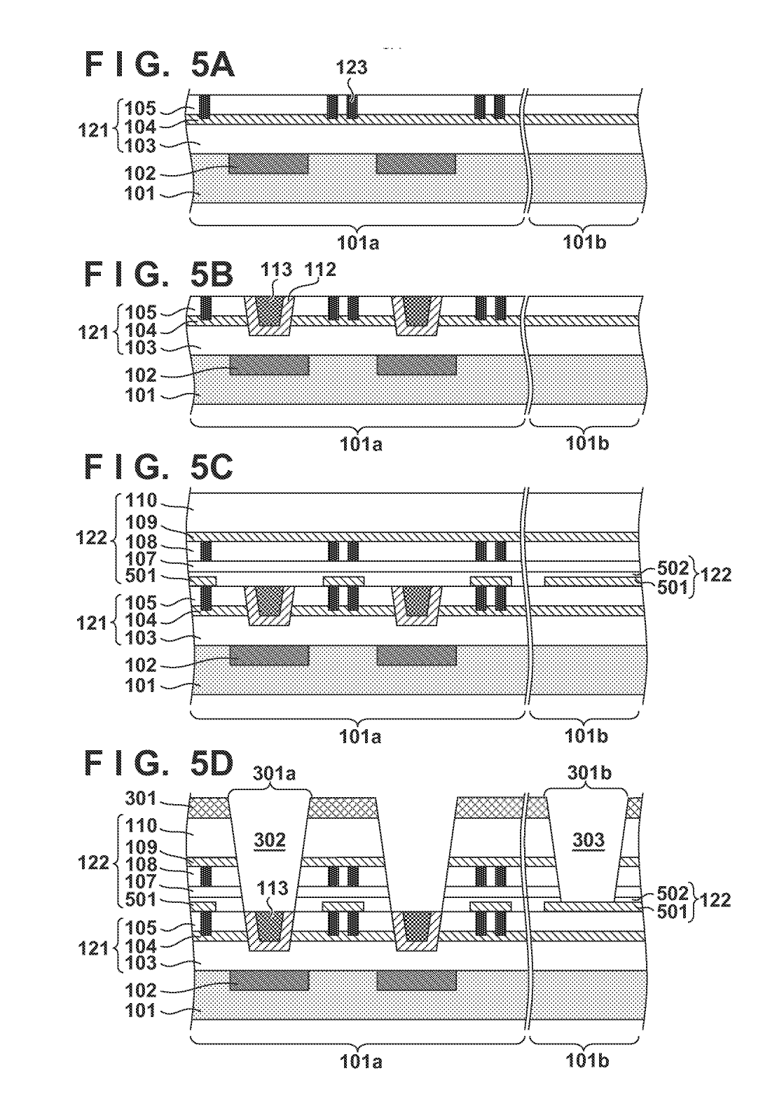

A method of manufacturing a solid-state imaging apparatus according to still another embodiment will be described next with reference to FIGS. 5A to 5D. The arrangement of the solid-state imaging apparatus manufactured by this method is the same as that of the solid-state imaging apparatus 100 in FIG. 1. First of all, in the same manner as in the process described with reference to FIG. 2A, insulating layers 103 to 105 are formed on a semiconductor substrate 101. This forms the structure shown in FIG. 5A.

Subsequently, in the same manner as in the process described with reference to FIGS. 2B to 2D, holes are formed in portions, of the insulating layers 103 to 105, which are located above corresponding photoelectric conversion portions 102, and an insulating layer 112 and a first filling member 113 are formed in each hole. This forms the structure shown in FIG. 5B.

Subsequently, after an insulating layer is formed, the insulating layer is patterned to form an insulating layer 501. After an insulating layer 502 is further formed on the insulating layer 501, insulating layers 107 to 110 are formed in the same manner as in the process described with reference to FIG. 3A. This forms the structure shown in FIG. 5C. An insulating layer 501 is made of, for example, silicon oxide. An insulating layer 502 is made of, for example, silicon carbide. The insulating layer 502 is formed on a non-effective pixel region 101b. On an effective pixel region 101a, the insulating layer 502 is not located above the photoelectric conversion portions 102 but is located above portions other than the photoelectric conversion portions 102. The insulating layer 501 located on the effective pixel region 101a can function as a copper diffusion preventing layer.

Subsequently, in the same manner as in the process described with reference to FIG. 3B, a resist pattern 301 is formed on the insulating layer 110, and holes 302 and 303 are formed by etching using the resist pattern 301 as a mask. This forms the structure shown in FIG. 5D. In the manufacturing method shown in FIGS. 5A to 5D, it is detected that the hole 303 has reached the insulating layer 501. In this embodiment, since the upper surface of the first filling member 113 is lower than the upper surface of the insulating layer 501, the holes 302 will not have reached the upper surfaces of the corresponding first filling members 113 when it is detected that the hole 303 has reached the insulating layer 501. For this reason, etching is continued for a predetermined time to expose the upper surfaces of the first filling members 113. Thereafter, in the same manner as in the process described with reference to FIG. 3C, a solid-state imaging apparatus is complete. In this manner, the insulating layer 501 functions as a member for detecting the end of etching.

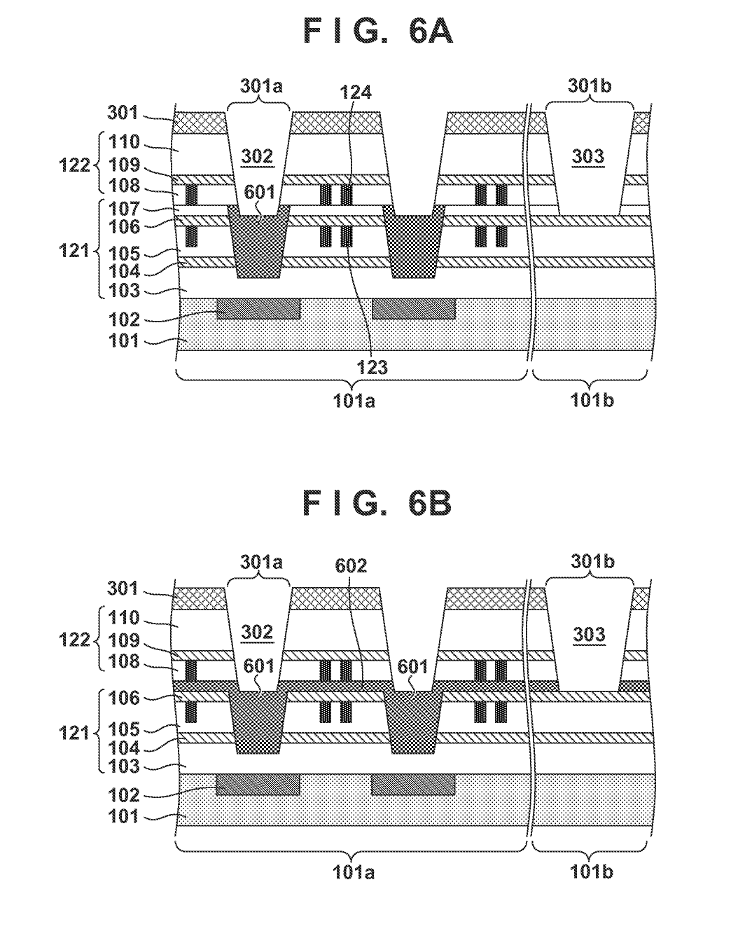

A method of manufacturing a solid-state imaging apparatus according to another embodiment will be described next with reference to FIG. 6A. The arrangement of the solid-state imaging apparatus manufactured by this method is the same as that of the solid-state imaging apparatus 100 in FIG. 1 except that it does not have the insulating layer 112. First of all, in the same manner as in the process shown in FIGS. 2A to 3A, the same structure as that shown in FIG. 3A is formed. In this embodiment, the insulating layer 112 is not formed, and first filling members 601 are in contact with an insulating film 121. Subsequently, in the same manner as in the process described with reference to FIG. 3B, a resist pattern 301 is formed on an insulating layer 110, and holes 302 and 303 are formed by etching using the resist pattern 301 as a mask. Etching may be finished when the hole 303 reaches an insulating layer 106, or may be continued for a predetermined time thereafter. Although the upper surface of each first filling member 601 may be etched, it is possible to control the amount of etching based on the timing when the insulating layer 106 is exposed, and hence a change in the shape of each first filling member 601 is suppressed. Thereafter, a solid-state imaging apparatus is complete in the same manner as in the process described with reference to FIG. 3C.

A method of manufacturing a solid-state imaging apparatus according to another embodiment will be described next with reference to FIG. 6B. This manufacturing method is the same as the manufacturing method in FIG. 6A except for the arrangement form of first filling members 601. Each first filling member 601 is coupled to the corresponding first filling member 601 on the adjacent pixel through a coupling portion 602, and has a T shape.

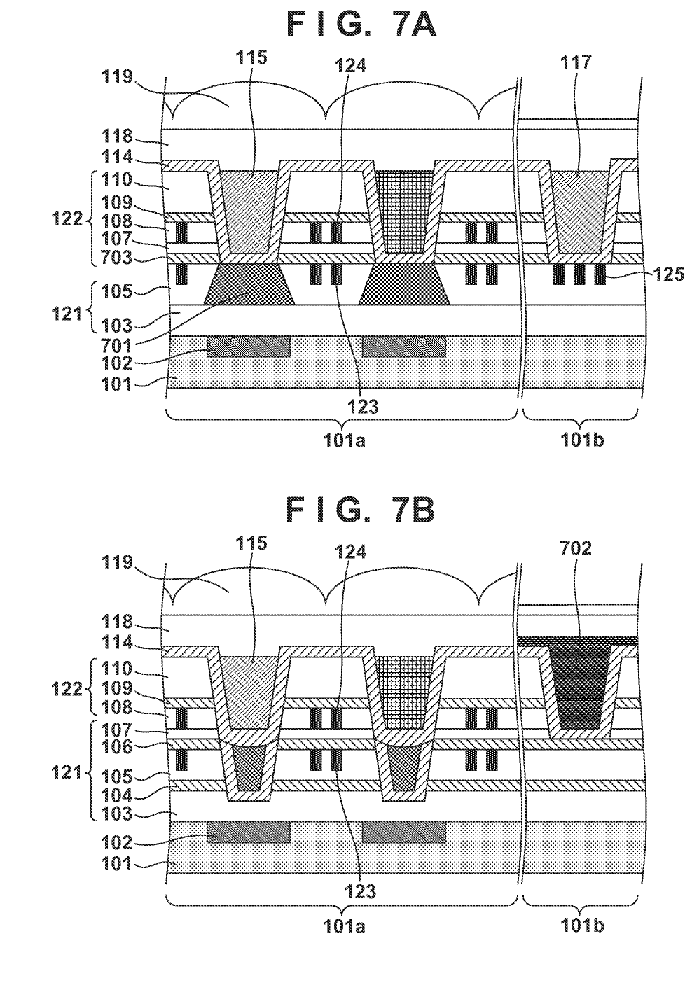

A method of manufacturing a solid-state imaging apparatus according to another embodiment will be described next with reference to FIGS. 7A and 7B. The solid-state imaging apparatus shown in FIG. 7A differs from the solid-state imaging apparatus 100 in the method of forming first filling members 701. First of all, an insulating layer 103 of an insulating film 121 is formed. A material layer for each first filling member 701 is formed on the insulating layer 103. The material layer is made of, for example, silicon nitride. Each first filling member 701 is formed by etching the material layer so as to leave a portion, of the material layer, which is located on a corresponding photoelectric conversion portion 102. At this time point, the first filling member 701 is not embedded. Thereafter, an insulating layer 105 of the insulating film 121 is formed to cover the side and upper surfaces of each first filling member 701. The insulating layer 105 is planarized to expose the upper surface of each first filling member 701. Electrically conductive patterns 123 and 125 are formed on the planarized insulating layer 105 by a damascene method. An insulating film 122 including insulating layers 106 to 110 and 703 is formed on the insulating layer 105 and the first filling member 701. Forming the insulating layer 703 as a silicon nitride layer or silicon carbide layer makes it possible to use the layer as a diffusion preventing layer of the electrically conductive patterns 123 and 125 made of copper. In this manner, the first filling members 701 can be formed by a method different from the method in which each filling member is embedded in the corresponding hole. This also makes it possible to form, for example, the first filling member 701 so as to have a tapered portion such that the area of the bottom surface is larger than that of the upper surface. In addition, this suppresses damage to the photoelectric conversion portions 102. A hole 303 is formed in a non-effective pixel region 101b so as to expose the insulating layer 105 and the electrically conductive pattern 125. It is possible to finish etching based on the timing when the insulating layer 105 and the electrically conductive pattern 125 are exposed. For example, it is possible to detect that the insulating layer 105 and the electrically conductive pattern 125 are exposed, in the following manner. It is possible to detect that the insulating layer 105 is exposed, based on a change in the emission intensity of the plasma generated by the gas generated when the insulating layer 105 or the insulating layer 703 is exposed to etching. Alternatively, it is possible to detect the end of etching based on a change in reflection of light when an electrically conductive pattern 125 is exposed upon irradiation of the electrically conductive pattern 125 with light such as laser light. In this manner, the insulating layer 105 or 703 or the electrically conductive pattern 125 functions as a member for detecting the end of etching.

The solid-state imaging apparatus shown in FIG. 7B differs from the solid-state imaging apparatus 100 in that it has a light-shielding member 702 instead of a third filling member 117. The light-shielding member 702 may be not only embedded in an aperture on a non-effective pixel region 101b but also formed on the entire non-effective pixel region 101b. The light-shielding member 702 is not formed on a photoelectric conversion portion 102. Such a solid-state imaging apparatus can also be manufactured in the same process as that shown in FIGS. 2A to 2D and 3A to 3C.

As an application of the solid-state imaging apparatus according to the respective embodiments, a camera in which the solid-state imaging apparatus is built in will be exemplarily explained. The concept of the camera includes not only an apparatus mainly aiming at image capturing but also an apparatus (for example, a personal computer or portable terminal) accessorily having an image capturing function. The camera includes the solid-state imaging apparatus according to the present invention exemplified as the embodiments, and a signal processing unit which processes a signal output from the solid-state imaging apparatus. This signal processing unit can include, for example, a processor which processes digital data based on the signal obtained from the solid-state imaging apparatus. An A/D converter for generating this digital data may be provided on the semiconductor substrate of the solid-state imaging apparatus or on another semiconductor substrate.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-264505, filed Dec. 20, 2013 which is hereby incorporated by reference herein in its entirety.

What is claimed is:

1. A method of manufacturing a solid-state imaging apparatus, the method comprising:
forming, above a substrate having an effective pixel region and a non-effective pixel region, a structure including a first member located above the effective pixel region, a second member located above the non-effective pixel region, and a third member covering the first member and the second member;
forming, above the third member, a mask having a first aperture located above the first member and a second aperture located above the second member; and
forming a first hole exposing the first member in the structure by etching the structure through the first aperture, and a second hole exposing the second member in the structure by etching the structure through the second aperture,
wherein in the etching, the first hole and the second hole are concurrently formed, and etching of the structure is finished based on that the second hole has reached the second member.

2. The method according to claim 1, wherein the first member is located above a photoelectric conversion portion in the effective pixel region.

3. The method according to claim 2, wherein the first member functions as a light waveguide.

4. The method according to claim 1, wherein the first member and the second member are made of different materials from each other.

5. The method according to claim 1, wherein the forming of the structure includes
forming a first insulating film above the substrate;
forming a hole in a portion of the first insulating film, the portion being located above the effective pixel region,
embedding the first member in the hole of the first insulating film, and
forming a second insulating film above the first insulating film after the first member is embedded, and
the second member comprises an insulating layer forming the first insulating film or an insulating layer forming the second insulating film.

6. The method according to claim 1, wherein a height of an upper surface of the first member from the substrate is higher than a height of an upper surface of the second member from the substrate.

7. The method according to claim 1, wherein a height of an upper surface of the first member from the substrate is equal to a height of an upper surface of the second member from the substrate.

8. The method according to claim 1, wherein a height of an upper surface of the first member from the substrate is lower than a height of an upper surface of the second member from the substrate.

9. The method according to claim 1, wherein in the etching, etching is continued for a predetermined time after it is detected that the second hole has reached the second member.

10. The method according to claim 1, wherein a width of the first aperture is equal to a width of the second aperture.

11. The method according to claim 1, further comprising embedding a material different from the first member into the first hole.

12. The method according to claim 1, further comprising embedding a light-shielding member in the second hole.

13. The method according to claim 1, wherein in the etching, it is detected that the second hole has reached the second member, based on a difference between a component of a gas generated during etching of a material on the second member and a component of a gas generated when the second member is exposed to etching.

14. A solid-state imaging apparatus comprising a substrate having an effective pixel region including a photoelectric conversion portion and a non-effective pixel region,
wherein, above the effective pixel region, a first filling member surrounded by a first insulating film in a first plane along a light-receiving surface of the photoelectric conversion portion and a second filling member surrounded by a second insulating film above the first insulating film in a second plane along the light-receiving surface of the photoelectric conversion portion are provided,
a third filling member surrounded by the second insulating film in the second plane is provided above the non-effective pixel region, and
the first insulating film is located between the third filling member and the substrate in the first plane.

15. The apparatus according to claim 14, wherein the first filling member is located above the photoelectric conversion portion, and a refractive index of the first filling member is higher than a refractive index of the first insulating film.

16. The apparatus according to claim 14, wherein the second filling member comprises a color filter located above the photoelectric conversion portion.

17. The apparatus according to claim 14, wherein the third filling member is located above a photoelectric conversion portion of a light-shielding pixel provided in the non-effective pixel region.
